(19) United States
(12) Patent Application Publication
(10) Pub. No.: US 2025/0126904 A1
(43) Pub. Date: Apr. 17, 2025

(54) PIXEL SENSORS AND METHODS OF MANUFACTURING THE SAME

(71) Applicant: Taiwan Semiconductor Manufacturing Co., Ltd., Hsinchu (TW)

(72) Inventors: Chih-Ping CHANG, Tainan City (TW); Ming-I WANG, Tainan City (TW); Shyh-Fann TING, Tainan City (TW)

(21) Appl. No.: 18/486,322

(22) Filed: Oct. 13, 2023

(51) Int. Cl. H01L 27/146; H04N 25/59

(52) U.S. Cl. CPC H10F 39/8027; H04N 25/59; H10F 39/014; H10F 39/024; H10F 39/182; H10F 39/8053; H10F 39/8063; H10F 39/807

(57) ABSTRACT

A metal grid of a pixel array may be patterned with different sized openings over photodiodes. As a result, a uniform pixel array of photodiodes with different sensitivities may be formed. For example, the pixel array may include low-sensitivity photodiodes (LSPDs), mid-sensitivity photodiodes (MSPDs), and high-sensitivity photodiodes (HSPDs). The LSPDs, MSPDs, and HSPDs have different capture rates. Therefore, a higher dynamic range is achieved by combining signals from LSPDs, MSPDs, and HSPDs. For example, the pixel array may achieve a dynamic range of approximately 140 decibels or higher due to its increased capacity. Additionally, the pixel array exhibits better dark performance as compared to a pixel array with a combination of large photodiodes (LPDs) and small photodiodes (SPDs). Because each photodiode in the pixel array is approximately a same size, photodiode leakage is reduced as compared with irregular pixel arrays including a combination of LPDs and SPDs.

### BACKGROUND

Complementary metal oxide semiconductor (CMOS) image sensors utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CMOS image sensor is often based on the three primary colors: red, green, and blue (R, G, B). Pixel sensors that sense light for each color can be defined through the use of a color filter that allows the light wavelength for a particular color to pass into a photodiode. Some pixel sensors may include a near infrared (NIR) pass filter, which blocks visible light and passes NIR light through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example pixel array described herein.

FIGS. 2A-2C are diagrams of example semiconductor structures described herein.

FIGS. 3A-3C are diagrams of example sub-pixels described herein.

FIGS. 4A-4C are diagrams of an example pixel sensor described herein.

FIGS. 5A-5C are diagrams of an example pixel sensor described herein.

FIGS. 6A-6C are diagrams of an example pixel sensor described herein.

FIGS. 7A-7C are diagrams of an example pixel sensor described herein.

FIGS. 8A-8C are diagrams of an example pixel sensor described herein.

FIGS. 9A-9E are diagrams of an example implementation described herein.

FIG. 10 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The dynamic range of an image sensor is based on a capacity of the sensor (for example, measured in electrons) relative to noise in the image sensor. The range is generally expressed in decibels (dB). In order to increase the dynamic range, an image sensor may include a pixel array with large photodiodes (LPDs) and small photodiodes (SPDs). The LPDs and SPDs have different capture rates. The capacity of the sensor is increased by combining signals from LPDs and SPDs, which results in a larger dynamic range. However, because LPDs and SPDs are different sizes, the pixel array is somewhat irregular, which reduces efficacy of isolation structures (for example, shallow trench isolations (STIs) and backside deep trench isolations (BDTIs)). Additionally, formation of the isolation structures may be complicated (e.g., resulting in increased power, processing resources, and raw material consumption and increasing process windows). As a result, dark performance is degraded by increased photodiode leakage.

One way to increase the dynamic range is to use a lateral overflow integration capacitor (LOFIC) sensor. The LOFIC sensor may achieve a dynamic range of approximately 120 dB due to its increased capacity as compared with LPD and SPD combinations. However, to increase the dynamic range of an LOFIC sensor further (e.g., to 140 dB and beyond), additional exposures are used, which results in motion artifacts and image blurs.

In order to reduce crosstalk between pixel sensors on a pixel array, a metal grid is often deposited with openings over photodiodes of the pixel array. Some implementations described herein provide techniques and apparatuses for patterning this metal grid with different sized openings over the photodiodes. As a result, a uniform pixel array of photodiodes with different sensitivities may be formed. For example, the pixel array may include low-sensitivity photodiodes (LSPDs), mid-sensitivity photodiodes (MSPDs), and high-sensitivity photodiodes (HSPDs). The LSPDs, MSPDs, and HSPDs have different capture rates. Therefore, a higher dynamic range is achieved by combining signals from LSPDs, MSPDs, and HSPDs. For example, the pixel array may achieve a dynamic range of approximately 140 dB or higher due to its increased capacity. Additionally, the pixel array exhibits better dark performance as compared to a pixel array with a combination of LPDs and SPDs. Because each photodiode in the pixel array is approximately a same size, photodiode leakage is reduced as compared with irregular pixel arrays including a combination of LPDs and SPDs.

In some implementations, the dynamic range is further extended with the addition of an LOFIC for the LSPDs of the pixel array. Additionally, or alternatively, multiple photodiodes of the pixel array may share a single microlens. Accordingly, phase detection auto focus (PDAF) may be performed using signals from HSPDs that share a single microlens.

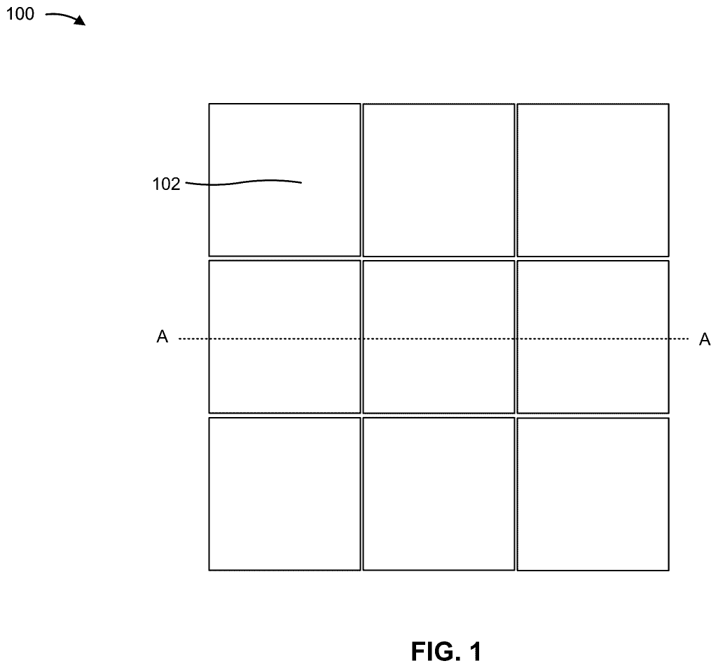

FIG. 1 is a diagram of an example pixel array 100 (or a portion thereof) described herein. The pixel array 100 may be included in an image sensor, such as a complementary metal oxide semiconductor (CMOS) image sensor, a back side illumination (BSI) CMOS image sensor, or another type of image sensor.

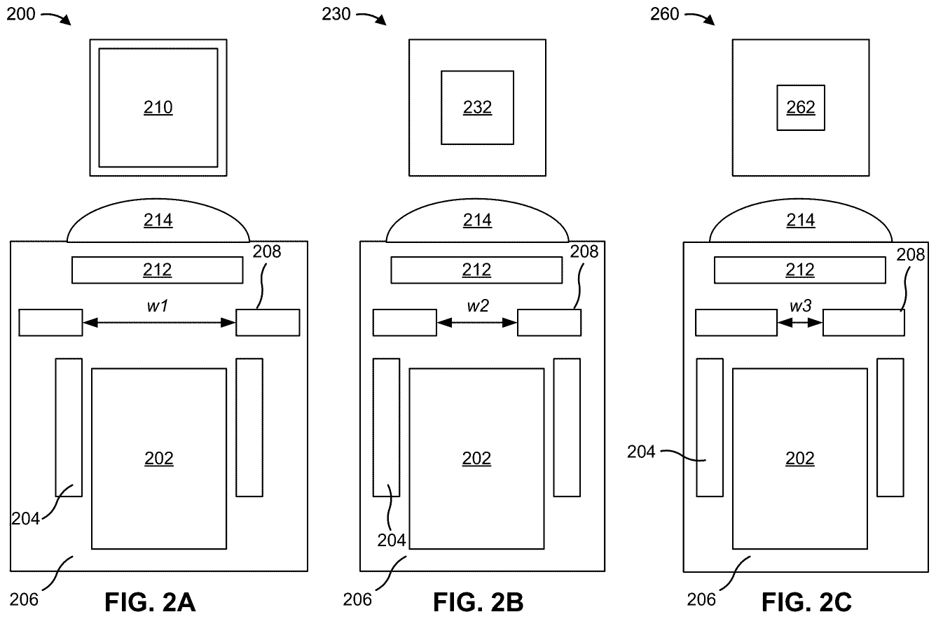

FIG. 1 shows a top-down view of the pixel array 100. As shown in FIG. 1, the pixel array 100 may include a plurality of pixel sensors 102. As further shown in FIG. 1, the pixel sensors 102 may be arranged in a grid. In some implementations, the pixel sensors 102 are square-shaped (as shown in the example in FIG. 2). In some implementations, the pixel sensors 102 include other shapes such as circle shapes, octagon shapes, diamond shapes, and/or other shapes.

The pixel sensors 102 may be configured to sense and/or accumulate incident light (e.g., light directed toward the pixel array 100). For example, a pixel sensor 102 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

The pixel array 100 may be electrically connected to a back-end-of-line (BEOL) metallization stack (not shown) of the image sensor. The BEOL metallization stack may electrically connect the pixel array 100 to control circuitry that may be used to measure the accumulation of incident light in the pixel sensors 102 and convert the measurements to an electrical signal.

As indicated above, FIG. 2 is provided as an example. Other examples may differ from what is described with regard to FIG. 2. For example, the pixel sensors 102 may be electrically and optically isolated by an isolation structure (e.g., as described in connection with FIGS. 2A and 2C), such as a deep trench isolation (DTI) structure. The isolation structure may include a plurality of interconnected trenches that are filled with a dielectric material, such as an oxide material. The trenches of the isolation structure may be included around the perimeters of the pixel sensors 102 such that the isolation structure surrounds the pixel sensors 102. Moreover, the trenches of the isolation structure may extend into a substrate in which the pixel sensors 102 are formed to surround the photodiodes and other structures of the pixel sensors 102 in the substrate. In some implementations, the isolation structure includes a back side DTI (BDTI) structure with a high aspect ratio that is formed from the back side of the pixel array 100.

FIG. 2A is a diagram of an example pixel sensor 200 described herein. The example pixel sensor 200 includes a metal grid opening associated with a large capacity; accordingly, a photodiode of the example pixel sensor 200 is an HSPD. In some implementations, the example pixel sensor 200 illustrated in FIG. 2A may include, or may be included in, the pixel array 100 (or a portion thereof). In some implementations, the example pixel sensor 200 may be included in an image sensor. The image sensor may be a CMOS image sensor, a BSI CMOS image sensor, or another type of image sensor.

The pixel sensor 200 may include a photodiode 202. A photodiode 202 may include a region of a substrate (e.g., substrate 206) that is doped with a plurality of types of ions to form a p-n junction or a PIN junction (e.g., a junction between a p-type portion, an intrinsic (or undoped) type portion, and an n-type portion). For example, the substrate may be doped with an n-type dopant to form a first portion (e.g., an n-type portion) of a photodiode 202 and a p-type dopant to form a second portion (e.g., a p-type portion) of the photodiode 202. The photodiode 202 may be configured to absorb photons of incident light. The absorption of photons causes the photodiode 202 to accumulate a charge (referred to as a photocurrent) due to the photoelectric effect. Here, photons bombard the photodiode 202, which causes emission of electrons of the photodiode 202. The emission of electrons causes the formation of electron-hole pairs, where the electrons migrate toward a cathode of the photodiode 202, and the holes migrate toward an anode, which produces the photocurrent.

An isolation structure 204 may surround the photodiode 202. The isolation structure 204 provides optical isolation by blocking or preventing diffusion or bleeding of light from the pixel sensor 200 to another pixel sensor, thereby reducing crosstalk between adjacent pixel sensors. The isolation structure 204 may include trenches or DTI structures that are coated or lined with an antireflective coating (ARC) and filled with a dielectric layer (e.g., over the ARC). The isolation structure 204 may be formed in a grid layout in which the isolation structure 204 extends around the perimeters of pixel sensors in a pixel array (e.g., pixel array 100) and intersects at various locations of the pixel array. In some implementations, the isolation structure 204 is formed in a backside of the substrate 206 and thus may be referred to as a BDTI structure.

The substrate 206 may include a semiconductor die substrate, a semiconductor wafer, or another type of substrate in which semiconductor pixels may be formed. In some implementations, the substrate 206 is formed of silicon (Si), a material including silicon, a III-V compound semiconductor material such as gallium arsenide (GaAs), a silicon on insulator (SOI), or another type of semiconductor material that is capable of generating a charge from photons of incident light.

A metal layer 208 may be included above and/or on the substrate 206 (e.g., over the photodiode 202 and the isolation structure 204). The metal layer 208 may include a metallic material such as tungsten (W), copper (Cu), aluminum (Al), cobalt (Co), nickel (Ni), titanium (Ti), tantalum (Ta), another conductive material, and/or an alloy including one or more of the foregoing. The metal layer 208 may be etched such that a grid structure is formed between pixel sensors in a pixel array (e.g., pixel array 100). For example, the grid structure may include a plurality of interconnected columns of the metal layer 208, where cross-sections of the columns are shown in the perspective of FIG. 2A. The grid structure may surround the perimeter of the pixel sensor 200 and may be configured to provide additional crosstalk reduction and/or mitigation in combination with the isolation structure 204.

In some implementations, to further reduce crosstalk, a dielectric layer and/or air gaps are included in the grid structure. For example, a dielectric layer may include an oxide material such as a silicon oxide (SiOₓ) (e.g., silicon dioxide (SiO₂)), a silicon nitride (SiNₓ), a silicon carbide (SiCₓ), a titanium nitride (TiNₓ), a tantalum nitride (TaNₓ), a hafnium oxide (HfOₓ), a tantalum oxide (TaOₓ), or an aluminum oxide (AlOₓ), or another dielectric material that is capable of providing optical isolation. Additionally, or alternatively, air gaps provide optical isolation because the index of refraction of air is very low (approximately less than 1.0001, which is very close to the index of refraction of vacuum, defined as 1), and thus incident light is very likely to experience total reflection off the air gaps.

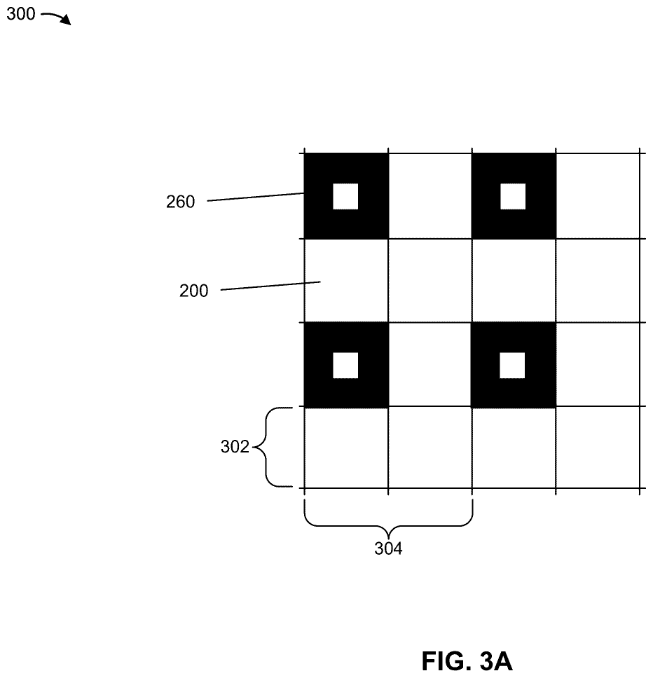

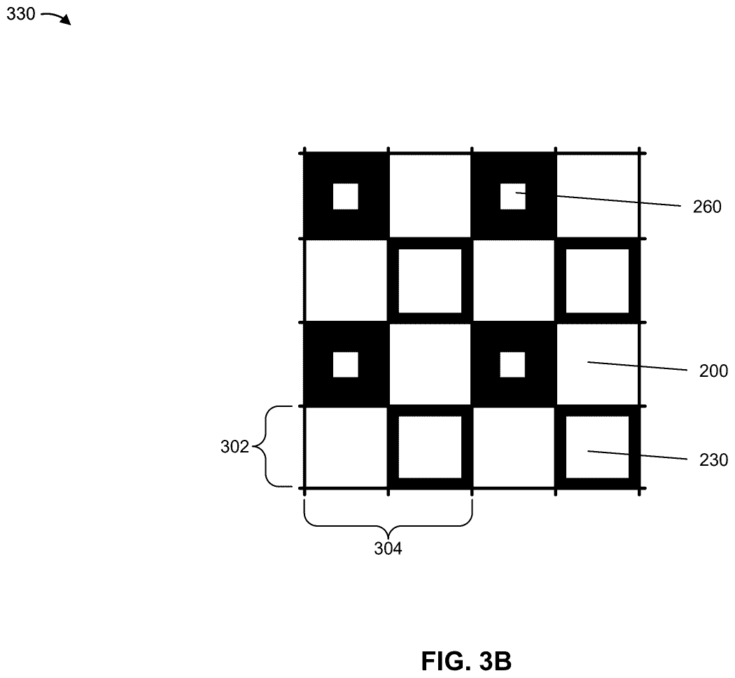

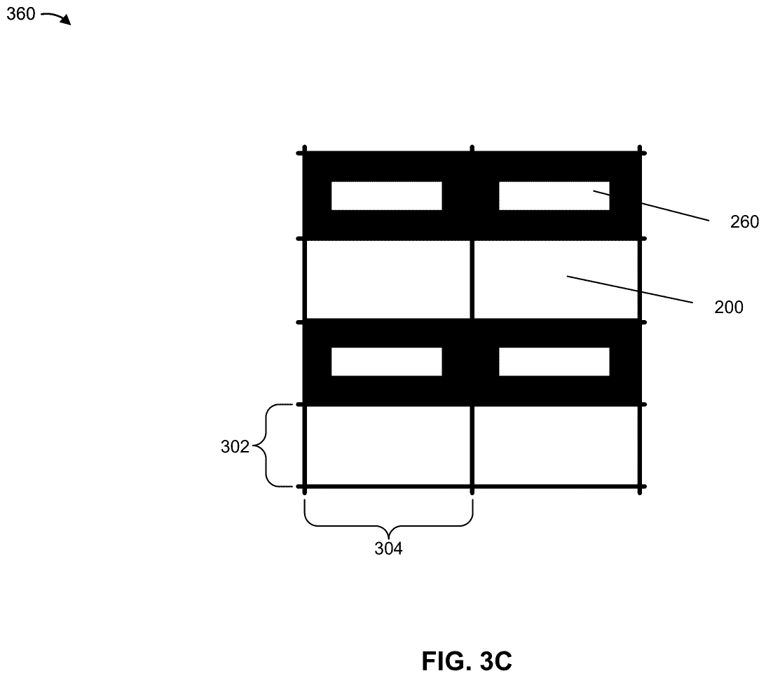

As shown in FIG. 2A, an opening 210 is formed in the metal layer 208 and over the photodiode 202. In some implementations, a ratio of a width (e.g., represented by w1 in FIG. 2A) associated with the opening 210 to a pitch associated with the pixel sensor 200 is in a range from approximately 0.8 to approximately 1.0. By selecting a ratio of at least 0.8, the photodiode 202 of the pixel sensor 200 functions as an HSPD-selecting a smaller ratio would block too much light. As shown in FIG. 2A, the width associated with the opening 210 may be approximately equal (e.g., within a 5% or 10% margin of error) to a length associated with the opening 210. As a result, the opening 210 is approximately square. Alternatively, the width associated with the opening 210 may be larger than the length associated with the opening 210, as described in connection with FIG. 3C.

In some implementations, the pixel sensor 200 further includes at least one light reduction filter (LRF). For example, an LRF may be formed over the photodiode 202 and under the metal layer 208 and/or may be formed over the metal layer 208 and under a color filter region 212. The at least one LRF may, in combination with the opening 210, tune an amount of light allowed to reach the photodiode 202.

A passivation layer may be included over the metal layer 208 and over portions of the substrate 206 that are not covered by the metal layer 208. The passivation layer may include an oxide material to provide protection for the layers beneath the passivation layer from the layers and structures that are formed above the passivation layer.

The color filter region 212 may be included over the photodiode 202 and on the passivation layer. The color filter region 212 may be configured to filter incident light to allow a particular wavelength of the incident light to pass to the photodiode 202. For example, the color filter region 212 may filter red light (and thus, the pixel sensor 200 may be a red pixel sensor), the color filter region 212 may filter green light (and thus, the pixel sensor 200 may be a green pixel sensor), or the color filter region 212 may filter blue light (and thus, the pixel sensor 200 may be a blue pixel sensor), among other examples. A blue filter region may permit the component of incident light near a 450 nanometer (nm) wavelength to pass through the color filter region 212 and block other wavelengths from passing. A green filter region may permit the component of incident light near a 550 nm wavelength to pass through the color filter region 212 and block other wavelengths from passing. A red filter region may permit the component of incident light near a 650 nm wavelength to pass through the color filter region 212 and block other wavelengths from passing. A yellow filter region may permit the component of incident light near a 580 nm wavelength to pass through the color filter region 212 and block other wavelengths from passing.

In some implementations, the color filter region 212 is non-discriminating or non-filtering (and thus, the pixel sensor 200 may be a white pixel sensor). A non-discriminating or non-filtering color filter region may include a material that permits all wavelengths of light to pass into the associated photodiode 202 (e.g., for purposes of determining overall brightness to increase light sensitivity for the image sensor). In some implementations, the color filter region 212 may be a near infrared (NIR) bandpass color filter region (and thus, the pixel sensor 200 may be an NIR pixel sensor). An NIR bandpass color filter region may include a material that permits the portion of incident light in an NIR wavelength range to pass to the associated photodiode 202 while blocking visible light from passing.

A microlens 214 may be included above and/or on the color filter region 212. The microlens 214 may be formed to focus incident light toward the photodiode 202 of the pixel sensor 200. The microlens 214 may be configured with a larger focal length because the photodiode 202 of the pixel sensor 200 is an HSPD.

FIG. 2B is a diagram of an example pixel sensor 230 described herein. The example pixel sensor 230 includes a metal grid opening associated with a medium capacity; accordingly, a photodiode of the example pixel sensor 230 is an MSPD. In some implementations, the example pixel sensor 230 illustrated in FIG. 2B may include, or may be included in, the pixel array 100 (or a portion thereof). In some implementations, the example pixel sensor 230 may be included in an image sensor. The image sensor may be a CMOS image sensor, a BSI CMOS image sensor, or another type of image sensor.

The example pixel sensor 230 of FIG. 2B is similar to the example pixel sensor 200 of FIG. 2A. As shown in FIG. 2B, a ratio of a width (e.g., represented by w2 in FIG. 2B) associated with an opening 232 in the metal layer 208 to a pitch associated with the pixel sensor 230 is in a range from approximately 0.5 to approximately 0.8. Selecting a ratio of at least 0.5 allows the photodiode 202 of the pixel sensor 200 to function as an MSPD-selecting a smaller ratio would block too much light. Selecting a ratio of no more than 0.8 also allows the photodiode 202 of the pixel sensor 200 to function as an MSPD-selecting a larger ratio would allow too much light. As shown in FIG. 2B, the width associated with the opening 232 may be approximately equal (e.g., within a 5% or 10% margin of error) to a length associated with the opening 232. As a result, the opening 232 is approximately square. Alternatively, the width associated with the opening 232 may be larger than the length associated with the opening 232, as described in connection with FIG. 3C.

FIG. 2C is a diagram of an example pixel sensor 260 described herein. The example pixel sensor 260 includes a metal grid opening associated with a low capacity; accordingly, a photodiode of the example pixel sensor 260 is an LSPD. In some implementations, the example pixel sensor 260 illustrated in FIG. 2C may include, or may be included in, the pixel array 100 (or a portion thereof). In some implementations, the example pixel sensor 260 may be included in an image sensor. The image sensor may be a CMOS image sensor, a BSI CMOS image sensor, or another type of image sensor.

The example pixel sensor 260 of FIG. 2C is similar to the example pixel sensor 200 of FIG. 2A. As shown in FIG. 2C, a ratio of a width (e.g., represented by w3 in FIG. 2C) associated with an opening 262 in the metal layer 208 to a pitch associated with the pixel sensor 260 is in a range from approximately 0.2 to approximately 0.5. Selecting a ratio of at least 0.2 allows the photodiode 202 of the pixel sensor 200 to function-selecting a smaller ratio would block too much light for the photodiode 202 to generate a detectable current. Selecting a ratio of no more than 0.5 allows the photodiode 202 of the pixel sensor 200 to function as an LSPD-selecting a larger ratio would allow too much light. As shown in FIG. 2C, the width associated with the opening 262 may be approximately equal (e.g., within a 5% or 10% margin of error) to a length associated with the opening 262. As a result, the opening 262 is approximately square. Alternatively, the width associated with the opening 262 may be larger than the length associated with the opening 262, as described in connection with FIG. 3C.

The pixel sensors 200, 230, and/or 260 may be combined within a pixel array (e.g., pixel array 100 of FIG. 1). The pixel sensors 200, 230, and 260 have different capture rates. Therefore, a higher dynamic range is achieved by combining signals from the pixel sensors 200, 230, and/or 260. As a result, the pixel array may achieve a dynamic range of approximately 140 dB or higher due to its increased capacity. Additionally, the pixel array exhibits better dark performance as compared to a pixel array with a combination of LPDs and SPDs.

Additionally, the pixel sensors 200, 230, and 260 are all formed to approximately a same size (e.g., each photodiode 202 has a volume within a 5% or 10% margin of error of other photodiodes). For example, a ratio of a size of one photodiode to a size of another photodiode is in a range from approximately 0.9 to approximately 1.1. As a result, photodiode leakage is reduced in the pixel array as compared with irregular pixel arrays including a combination of LPDs and SPDs.

As indicated above, FIGS. 2A-2C are provided as examples. Other examples may differ from what is described with regard to FIGS. 2A-2C.

FIG. 3A is a diagram of an example pixel array 300 described herein. The example pixel array 300 includes approximately square HSPDs in combination with approximately square LSPDs. In some implementations, the example pixel array 300 may be included in an image sensor. The image sensor may be a CMOS image sensor, a BSI CMOS image sensor, or another type of image sensor.

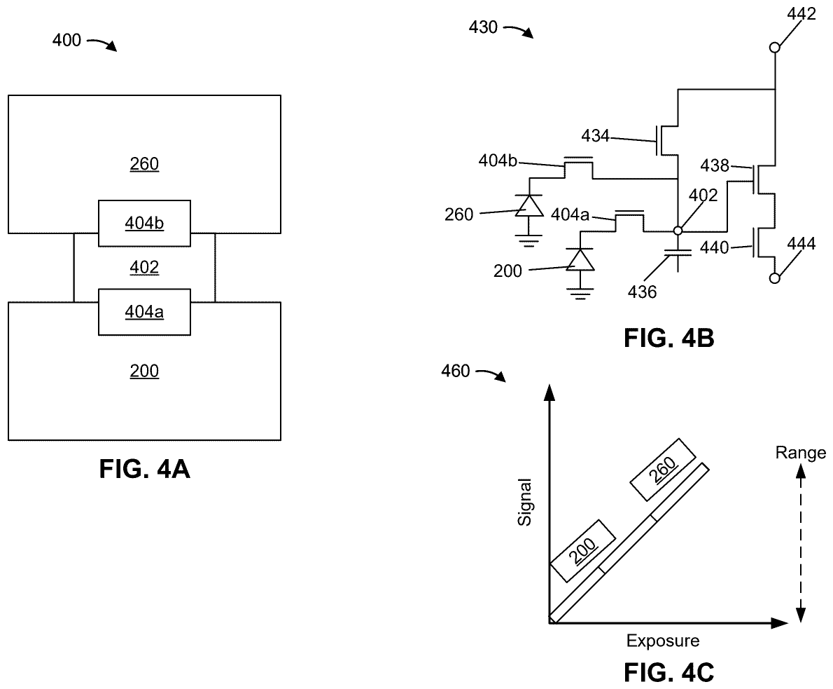

As shown in FIG. 3A, the pixel array 300 includes HSPDs (e.g., included in pixel sensor 200, as described in connection with FIG. 2A) and LSPDs (e.g., included in pixel sensor 260, as described in connection with FIG. 2C). The pixel array 300 may include a plurality of sub-pixels, such as sub-pixel 302. For example, each sub-pixel is a single pixel sensor 200 or a single pixel sensor 260 in FIG. 3A. A “sub-pixel” is at least one pixel sensor that shares circuitry and/or a microlens (e.g., as described in connection with FIGS. 4A-4C, 5A-5C, 6A-6C, 7A-7C, and 8A-8C) with at least one other sub-pixel. In FIG. 3A, three HSPDs and one LSPD may be included across four sub-pixels that share circuitry and/or a microlens and that form a pixel 304 in the pixel array 300.

FIG. 3B is a diagram of an example pixel array 330 described herein. The example pixel array 330 includes approximately square HSPDs in combination with approximately square MSPDs and approximately square LSPDs. In some implementations, the example pixel array 330 may be included in an image sensor. The image sensor may be a CMOS image sensor, a BSI CMOS image sensor, or another type of image sensor.

As shown in FIG. 3B, the pixel array 330 includes HSPDs (e.g., included in pixel sensor 200, as described in connection with FIG. 2A), MSPDs (e.g., included in pixel sensor 230, as described in connection with FIG. 2B), and LSPDs (e.g., included in pixel sensor 260, as described in connection with FIG. 2C). The pixel array 330 may include a plurality of sub-pixels, such as sub-pixel 302. In FIG. 3B, two HSPDs, one MSPD, and one LSPD may be included across four sub-pixels that share circuitry and/or a microlens and that form a pixel 304 in the pixel array 330.

FIG. 3C is a diagram of an example pixel array 360 described herein. The example pixel array 330 includes elongated HSPDs in combination with elongated LSPDs. In some implementations, the example pixel array 360 may be included in an image sensor. The image sensor may be a CMOS image sensor, a BSI CMOS image sensor, or another type of image sensor.

As shown in FIG. 3C, the pixel array 360 includes HSPDs (e.g., included in pixel sensor 200, as described in connection with FIG. 2A) and LSPDs (e.g., included in pixel sensor 260, as described in connection with FIG. 2C). The pixel array 360 may include a plurality of sub-pixels, such as sub-pixel 302. Each sub-pixel is associated with an opening in a metal layer that has a larger width than length, as shown in FIG. 3C. Additionally, in FIG. 3C, two HSPD and one LSPD may be included across two sub-pixels that share circuitry and/or a microlens and that form a pixel 304 in the pixel array 330.

As indicated above, FIGS. 3A-3C are provided as examples. Other examples may differ from what is described with regard to FIGS. 3A-3C.

FIG. 4A is a diagram of an example pixel 400 described herein. The example pixel 400 includes a pixel sensor 200 as a sub-pixel with an HSPD in combination with a pixel sensor 260 as a sub-pixel with an LSPD. In some implementations, the example pixel 400 may be included in an image sensor. The image sensor may be a CMOS image sensor, a BSI CMOS image sensor, or another type of image sensor.

As shown in FIG. 4A, the pixel sensor 200 and the pixel sensor 260 share a floating diffusion (FD) node 402. Accordingly, a transfer gate 404a, associated with the pixel sensor 200, and a transfer gate 404b, associated with the pixel sensor 260, both direct signals to the same FD node 402. Using the same FD node 402 simplifies design and thus conserves power, processing resources, and raw materials during fabrication.

In some implementations, the pixel sensors 200 and 260 may share a microlens. Using a shared microlens simplifies design and thus conserves power, processing resources, and raw materials during fabrication. Alternatively, the pixel sensor 200 may use a different microlens (e.g., a microlens with a shorter focal length) than the pixel sensor 260. Using different microlenses can increase accuracy of signals from each pixel sensor.

FIG. 4B is a diagram of example circuitry 430 described herein. The example circuitry 430 is shown with reference to example pixel 400 of FIG. 4A. In some implementations, the example circuitry 430 may be included in an image sensor. The image sensor may be a CMOS image sensor, a BSI CMOS image sensor, or another type of image sensor.

As shown in FIG. 4B, signals from the photodiode of the pixel sensor 200 are controlled by the transfer gate 404a, and signals from the photodiode of the pixel sensor 260 are controlled by the transfer gate 404b. Additionally, a reset gate 434 uses a grounding node 442 to reset the pixel 400 to zero charge. In some implementations, in order to store additional charge from the pixel sensors 200 and 260 in brighter conditions, a dual conversion gain (DCG) capacitor 436 is included near the FD node 402. A source follower (SF) transistor 438 and row selector (RS) transistor 440 control output of signals from the pixel sensors 200 and 260 to a readout node 444.

FIG. 4C is a diagram of example range graph 460 described herein. The example range graph 460 is shown with reference to example pixel 400 of FIG. 4A. As shown in FIG. 4C, a total capacity of the pixel 400 is increased because an exposure time associated with the pixel sensor 260 follows an exposure time associated with the pixel sensor 200. As a result, a total signal achieved by combining signals from the pixel sensors 200 and 260 is larger and thus results in a larger dynamic range for the pixel 400 (e.g., at least 140 dB).

As indicated above, FIGS. 4A-4C are provided as an example. Other examples may differ from what is described with regard to FIGS. 4A-4C. For example, an MSPD may be used in place of the HSPD or the LSPD.

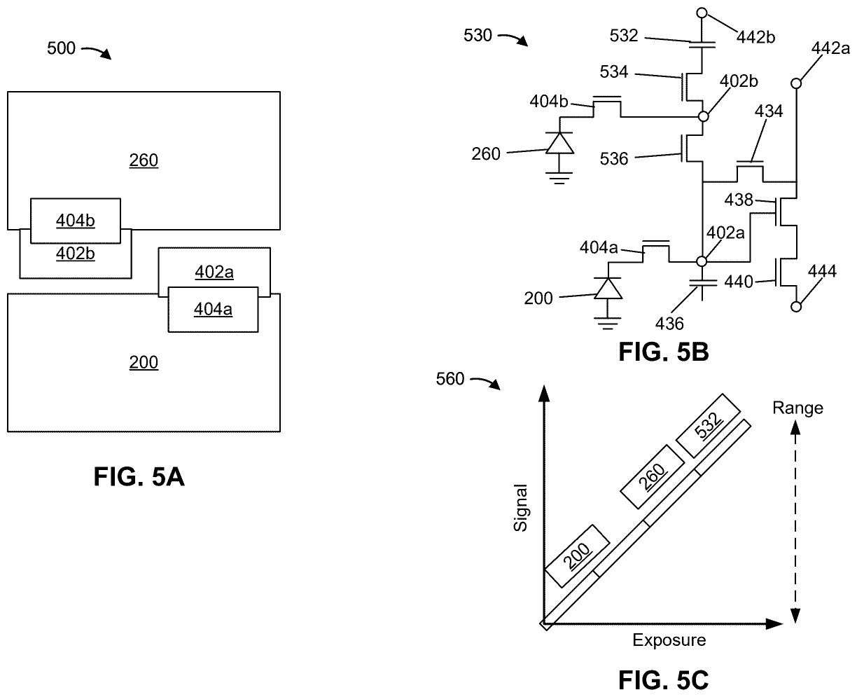

FIG. 5A is a diagram of an example pixel 500 described herein. The example pixel 500 includes a pixel sensor 200 as a sub-pixel with an HSPD in combination with a pixel sensor 260 as a sub-pixel with an LSPD. In some implementations, the example pixel 500 may be included in an image sensor. The image sensor may be a CMOS image sensor, a BSI CMOS image sensor, or another type of image sensor.

As shown in FIG. 5A, the pixel sensor 200 is associated with a first FD node 402a, and the pixel sensor 260 is associated with a second FD node 402b. Additionally, a transfer gate 404a directs signals from the pixel sensor 200 to the first FD node 402a, and a transfer gate 404b directs signals from the pixel sensor 260 to the second FD node 402b. Using separate FD nodes allows for use of an LOFIC to further increase dynamic range of the pixel 500.

In some implementations, the pixel sensors 200 and 260 may share a microlens. Using a shared microlens simplifies design and thus conserves power, processing resources, and raw materials during fabrication. Alternatively, the pixel sensor 200 may use a different microlens (e.g., a microlens with a shorter focal length) than the pixel sensor 260. Using different microlenses can increase accuracy of signals from each pixel sensor.

FIG. 5B is a diagram of example circuitry 530 described herein. The example circuitry 530 is shown with reference to example pixel 500 of FIG. 5A. In some implementations, the example circuitry 530 may be included in an image sensor. The image sensor may be a CMOS image sensor, a BSI CMOS image sensor, or another type of image sensor.

As shown in FIG. 5B, signals from the photodiode of the pixel sensor 200 are directed by the transfer gate 404a to the FD node 402a, and signals from the photodiode of the pixel sensor 260 are directed by the transfer gate 404b to the FD node 402b. Additionally, a reset gate 434 uses a grounding node 442a to reset the pixel 500 to zero charge. In some implementations, in order to store additional charge from the pixel sensor 200 in brighter conditions, a DCG capacitor 436 is included near the FD node 402a. Similarly, in order to store additional charge from the pixel sensor 200, an LOFIC 532 is included near the FD node 402b and is controlled by a gain control (GC) gate 534. The LOFIC 532 is also associated with a grounding node 442b. An SF transistor 438 and an RS transistor 440, in combination with a GC gate 536, control output of signals from the pixel sensors 200 and 260 to a readout node 444.

FIG. 5C is a diagram of example range graph 560 described herein. The example range graph 560 is shown with reference to example pixel 500 of FIG. 5A. As shown in FIG. 5C, a total capacity of the pixel 500 is increased because an exposure time associated with the pixel sensor 260 follows an exposure time associated with the pixel sensor 200. Additionally, an exposure time associated with the pixel sensor 260 is further increased by the LOFIC 532. As a result, a total signal achieved is larger and thus results in a larger dynamic range for the pixel 500 (e.g., at least 140 dB).

As indicated above, FIGS. 5A-5C are provided as an example. Other examples may differ from what is described with regard to FIGS. 5A-5C. For example, an MSPD may be used in place of the HSPD or the LSPD.

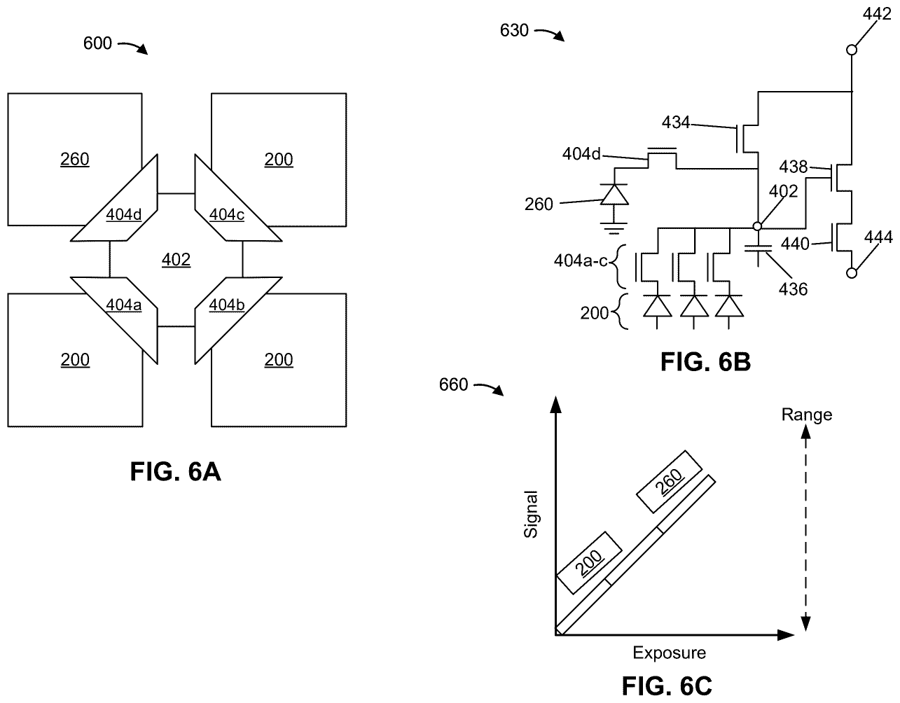

FIG. 6A is a diagram of an example pixel 600 described herein. The example pixel 600 includes three pixel sensors 200 as sub-pixels with HSPDs in combination with a pixel sensor 260 as a sub-pixel with an LSPD. In some implementations, the example pixel 600 may be included in an image sensor. The image sensor may be a CMOS image sensor, a BSI CMOS image sensor, or another type of image sensor.

As shown in FIG. 6A, the pixel sensors 200 and the pixel sensor 260 share an FD node 402. Accordingly, transfer gates 404a, 404b, and 404c, associated with the pixel sensors 200, and a transfer gate 404d, associated with the pixel sensor 260, all direct signals to the same FD node 402. Using the same FD node 402 simplifies design and thus conserves power, processing resources, and raw materials during fabrication.

In some implementations, the pixel sensors 200 and 260 may share a microlens. Using a shared microlens simplifies design and thus conserves power, processing resources, and raw materials during fabrication. Additionally, using a shared microlens allows for PDAF to be performed using signals from different HSPDs in the pixel 600. For example, PDAF in a horizontal direction may be performed by using the transfer gate 404a separately from the transfer gate 404b. Similarly, PDAF in a vertical direction may be performed by using the transfer gate 404b separately from the transfer gate 404c. Alternatively, the pixel sensors 200 may use different microlenses (e.g., a microlens with a shorter focal length) than the pixel sensor 260. Using different microlenses can increase accuracy of signals from each pixel sensor.

FIG. 6B is a diagram of example circuitry 630 described herein. The example circuitry 630 is shown with reference to example pixel 600 of FIG. 6A. In some implementations, the example circuitry 630 may be included in an image sensor. The image sensor may be a CMOS image sensor, a BSI CMOS image sensor, or another type of image sensor.

As shown in FIG. 6B, signals from the photodiodes of the pixel sensors 200 are controlled by the transfer gates 404a, 404b, and 404c, and signals from the photodiode of the pixel sensor 260 are controlled by the transfer gate 404d. Additionally, a reset gate 434 uses a grounding node 442 to reset the pixel 600 to zero charge. In some implementations, in order to store additional charge from the pixel sensors 200 and 260 in brighter conditions, a DCG capacitor 436 is included near the FD node 402. An SF transistor 438 and an RS transistor 440 control output of signals from the pixel sensors 200 and 260 to a readout node 444.

FIG. 6C is a diagram of example range graph 660 described herein. The example range graph 660 is shown with reference to example pixel 600 of FIG. 6A. As shown in FIG. 6C, a total capacity of the pixel 600 is increased because an exposure time associated with the pixel sensor 260 follows an exposure time associated with the pixel sensors 200. As a result, a total signal achieved by combining signals from the pixel sensors 200 and 260 is larger and thus results in a larger dynamic range for the pixel 600 (e.g., at least 140 dB).

As indicated above, FIGS. 6A-6C are provided as an example. Other examples may differ from what is described with regard to FIGS. 6A-6C. For example, a different combination of LSPDs and HSPDs may be used (e.g., two LSPDs with two HSPDs, among other examples).

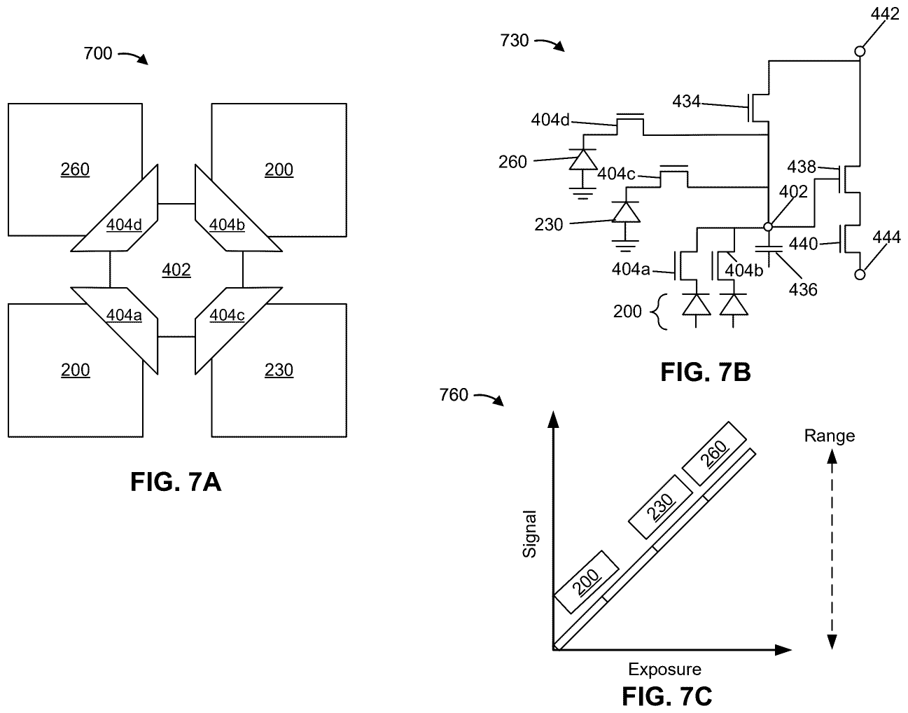

FIG. 7A is a diagram of an example pixel 700 described herein. The example pixel 700 includes two pixel sensors 200 as sub-pixels with HSPDs in combination with a pixel sensor 230 as a sub-pixel with an MSPD and a pixel sensor 260 as a sub-pixel with an LSPD. In some implementations, the example pixel 700 may be included in an image sensor. The image sensor may be a CMOS image sensor, a BSI CMOS image sensor, or another type of image sensor.

As shown in FIG. 7A, the pixel sensors 200, 230, and 260 share an FD node 402. Accordingly, transfer gates 404a and 404b, associated with the pixel sensors 200, a transfer gate 404c, associated with the pixel sensor 230, and a transfer gate 404d, associated with the pixel sensor 260, all direct signals to the same FD node 402. Using the same FD node 402 simplifies design and thus conserves power, processing resources, and raw materials during fabrication.

In some implementations, the pixel sensors 200, 230, and 260 may share a microlens. Using a shared microlens simplifies design and thus conserves power, processing resources, and raw materials during fabrication. Alternatively, the pixel sensors 200 may use different microlenses (e.g., a microlens with a shorter focal length) than the pixel sensor 230 and the pixel sensor 260. Using different microlenses can increase accuracy of signals from each pixel sensor.

FIG. 7B is a diagram of example circuitry 730 described herein. The example circuitry 730 is shown with reference to example pixel 700 of FIG. 7A. In some implementations, the example circuitry 730 may be included in an image sensor. The image sensor may be a CMOS image sensor, a BSI CMOS image sensor, or another type of image sensor.

As shown in FIG. 7B, signals from the photodiodes of the pixel sensors 200 are controlled by the transfer gates 404a and 404b, signals from the photodiode of the pixel sensor 230 are controlled by the transfer gate 404c, and signals from the photodiode of the pixel sensor 260 are controlled by the transfer gate 404d. Additionally, a reset gate 434 uses a grounding node 442 to reset the pixel 700 to zero charge. In some implementations, in order to store additional charge from the pixel sensors 200, 230, and 260 in brighter conditions, a DCG capacitor 436 is included near the FD node 402. An SF transistor 438 and an RS transistor 440 control output of signals from the pixel sensors 200, 230, and 260 to a readout node 444.

FIG. 7C is a diagram of example range graph 760 described herein. The example range graph 760 is shown with reference to example pixel 700 of FIG. 7A. As shown in FIG. 7C, a total capacity of the pixel 700 is increased because an exposure time associated with the pixel sensor 260 follows an exposure time associated with the pixel sensor 230, which in turn follows an exposure time associated with the pixel sensors 200. As a result, a total signal achieved by combining signals from the pixel sensors 200, 230, and 260 is larger and thus results in a larger dynamic range for the pixel 700 (e.g., at least 140 dB).

As indicated above, FIGS. 7A-7C are provided as an example. Other examples may differ from what is described with regard to FIGS. 7A-7C. For example, a different combination of LSPDs, MSPDs, and HSPDs may be used (e.g., two LSPDs with an MSPD and an HSPD, among other examples).

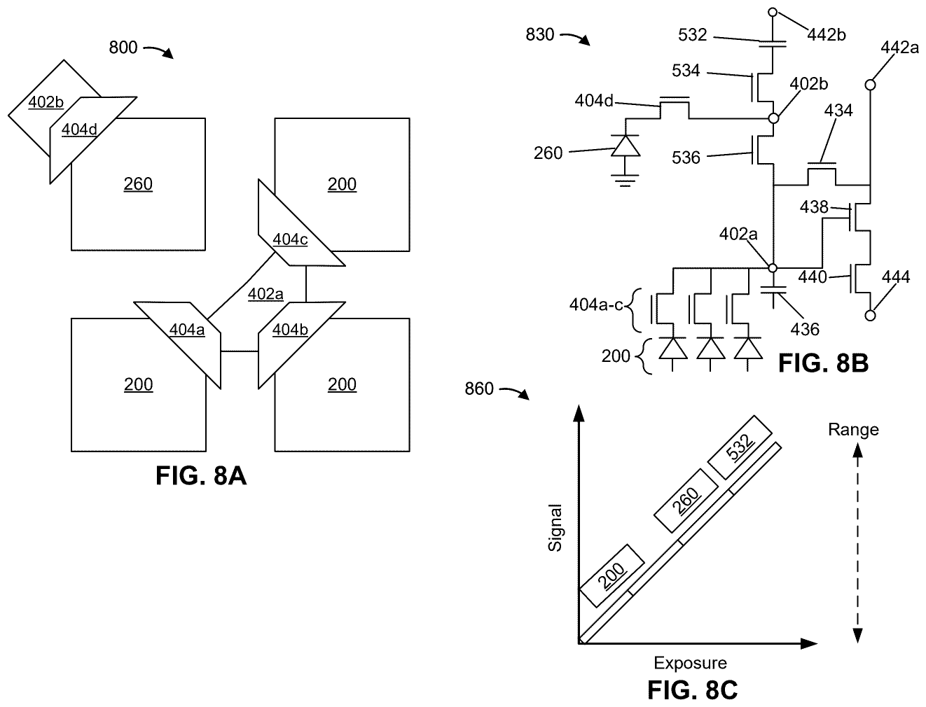

FIG. 8A is a diagram of an example pixel 800 described herein. The example pixel 800 includes three pixel sensors 200 as sub-pixels with HSPDs in combination with a pixel sensor 260 as a sub-pixel with an LSPD. In some implementations, the example pixel 800 may be included in an image sensor. The image sensor may be a CMOS image sensor, a BSI CMOS image sensor, or another type of image sensor.

As shown in FIG. 8A, the pixel sensors 200 are associated with a first FD node 402a, and the pixel sensor 260 is associated with a second FD node 402b. Additionally, transfer gates 404a, 404b, and 404c direct signals from the pixel sensors 200 to the first FD node 402a, and a transfer gate 404d directs signals from the pixel sensor 260 to the second FD node 402b. Using separate FD nodes allows for use of an LOFIC to further increase dynamic range of the pixel 800.

In some implementations, the pixel sensors 200 and 260 may share a microlens. Using a shared microlens simplifies design and thus conserves power, processing resources, and raw materials during fabrication. Additionally, using a shared microlens allows for PDAF to be performed using signals from different HSPDs in the pixel 800. For example, PDAF in a horizontal direction may be performed by using the transfer gate 404a separately from the transfer gate 404b. Similarly, PDAF in a vertical direction may be performed by using the transfer gate 404b separately from the transfer gate 404c. Alternatively, the pixel sensors 200 may use different microlenses (e.g., a microlens with a shorter focal length) than the pixel sensor 260. Using different microlenses can increase accuracy of signals from each pixel sensor.

FIG. 8B is a diagram of example circuitry 830 described herein. The example circuitry 830 is shown with reference to example pixel 800 of FIG. 8A. In some implementations, the example circuitry 830 may be included in an image sensor. The image sensor may be a CMOS image sensor, a BSI CMOS image sensor, or another type of image sensor.

As shown in FIG. 8B, signals from the photodiode of the pixel sensors 200 are directed by the transfer gates 404a, 404b, and 404c to the FD node 402a, and signals from the photodiode of the pixel sensor 260 are directed by the transfer gate 404d to the FD node 402b. Additionally, a reset gate 434 uses a grounding node 442a to reset the pixel 800 to zero charge. In some implementations, in order to store additional charge from the pixel sensors 200 in brighter conditions, a DCG capacitor 436 is included near the FD node 402a. Similarly, in order to store additional charge from the pixel sensor 200, an LOFIC 532 is included near the FD node 402b and is controlled by a GC gate 534. The LOFIC 532 is also associated with a grounding node 442b. An SF transistor 438 and an RS transistor 440, in combination with a GC gate 536, control output of signals from the pixel sensors 200 and 260 to a readout node 444.

FIG. 8C is a diagram of example range graph 860 described herein. The example range graph 860 is shown with reference to example pixel 800 of FIG. 8A. As shown in FIG. 8C, a total capacity of the pixel 800 is increased because an exposure time associated with the pixel sensor 260 follows an exposure time associated with the pixel sensor 200. Additionally, an exposure time associated with the pixel sensor 260 is further increased by the LOFIC 532. As a result, a total signal achieved is larger and thus results in a larger dynamic range for the pixel 800 (e.g., at least 140 dB).

As indicated above, FIGS. 8A-8C are provided as an example. Other examples may differ from what is described with regard to FIGS. 8A-8C. For example, a different combination of LSPDs and HSPDs may be used (e.g., two LSPDs with two HSPDs, among other examples).

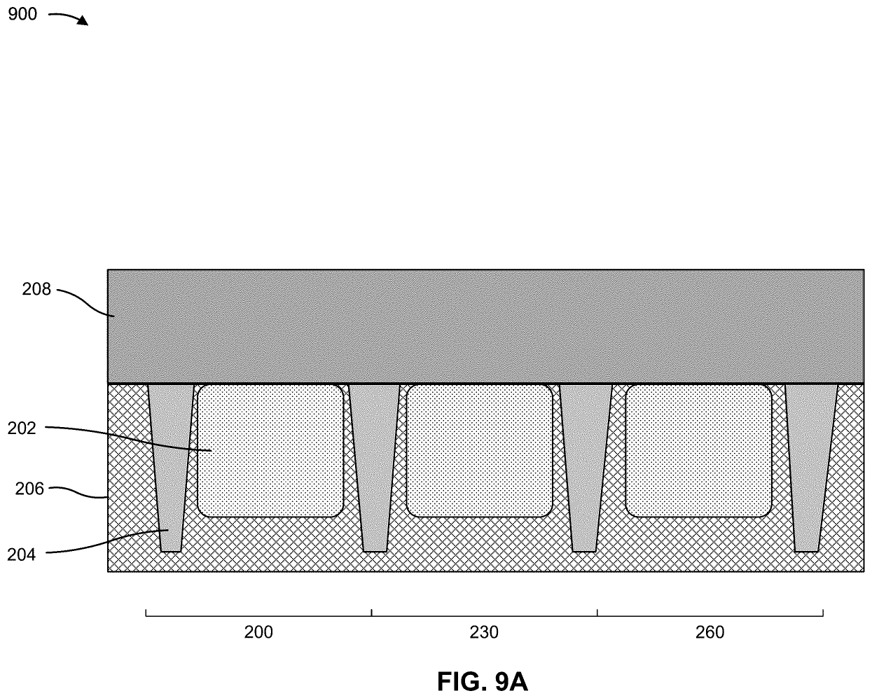

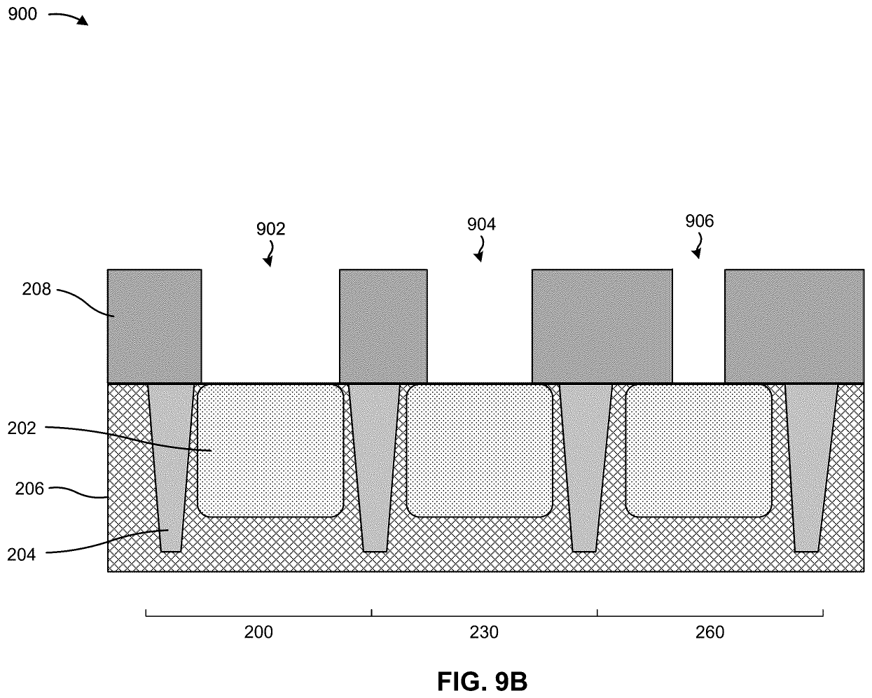

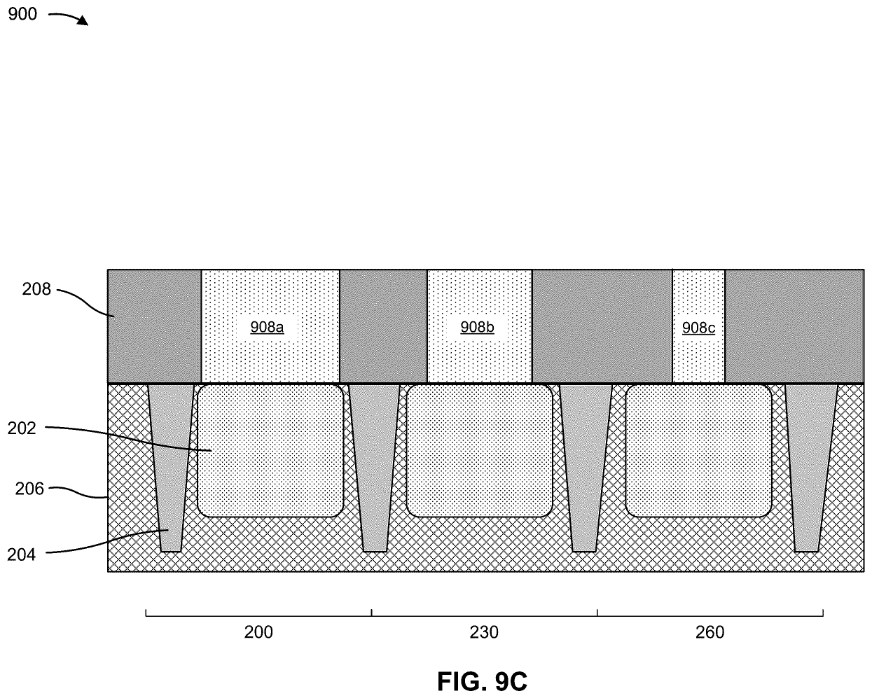

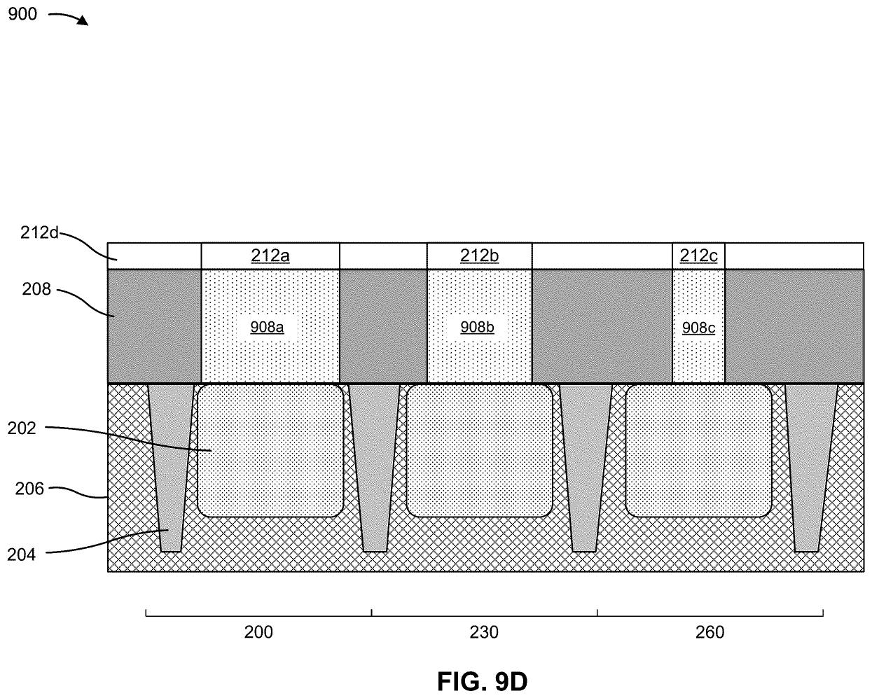

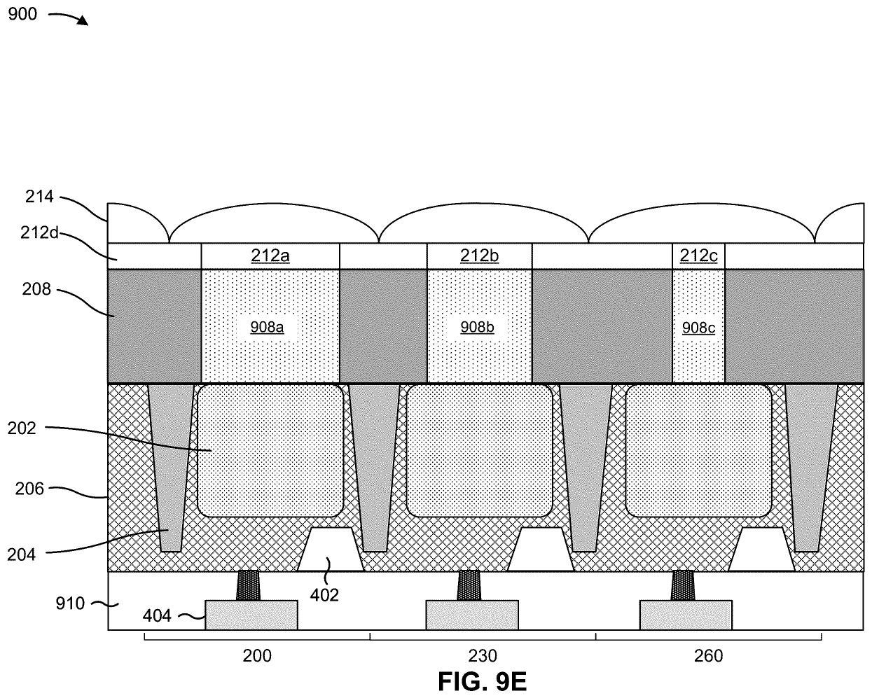

FIGS. 9A-9E are diagrams of an example implementation 900 described herein. The example implementation 900 may be an example process or method for forming a pixel array with differently sized openings in a metal grid. The techniques described in connection with FIGS. 9A-9E result in photodiodes that are approximately a same size but associated with differently sized openings in the metal grid.

As shown in FIG. 9A, the example process for forming the pixel array may be performed in connection with a substrate 206. As described above, the substrate 206 may include a semiconductor die substrate, a semiconductor wafer, a stacked semiconductor wafer, or another type of substrate in which semiconductor pixels may be formed. For example, the substrate 206 may be formed of silicon (Si) (e.g., a silicon substrate), a material including silicon, a III-V compound semiconductor material such as gallium arsenide (GaAs), an SOI, or another type of semiconductor material that is capable of generating a charge from photons of incident light. In some implementations, the substrate 206 is formed of a doped material (e.g., a p-doped material or an n-doped material) such as a doped silicon.

Additionally, the substrate 206 may have a photodiodes 202 formed therein. For example, an ion implantation tool may dope portions of the substrate 206 using an ion implantation technique to form the photodiode 202. The substrate 206 may be doped with a plurality of types of ions to form a p-n junction for each photodiode 202. For example, the substrate 206 may be doped with an n-type dopant to form a first portion (e.g., an n-type portion) of the photodiodes 202 and a p-type dopant to form a second portion (e.g., a p-type portion) of the photodiodes 202. In some implementations, another technique is used to form the photodiodes 202, such as diffusion.

As further shown in FIG. 9A, an isolation structure 204 (e.g., a DTI structure) may be included in the substrate 206 at least partially surrounding the photodiodes 202. The isolation structure 204 may be coated or lined with an ARC and filled with a dielectric layer (e.g., over the ARC).

As shown in FIG. 9A, a metal layer 208 may be formed. For example, a deposition tool may form the metal layer 208 over and/or on a frontside surface of the substrate 206 (e.g., over the photodiodes 202, the isolation structure 204, and exposed portions of the substrate 206) using a spin-coating technique, a chemical vapor deposition (CVD) technique, a physical vapor deposition (PVD) technique, an atomic layer deposition (ALD) technique, and/or another deposition technique. In some implementations, the metal layer 208 may be formed over a dielectric layer and/or a buffer layer over the photodiodes 202, the isolation structure 204, and exposed portions of the substrate 206. In some implementations, a planarization tool planarizes the metal layer 208 after deposition (e.g., using chemical mechanical planarization (CMP)). Although the example implementation 900 shows the metal layer 208 being formed directly on the isolation structure 204, other implementations may include a passivation layer formed on the isolation structure 204 (and optionally on the photodiodes 202 and/or exposed portions of the substrate 206). Accordingly, the passivation layer may protect the isolation structure 204 and/or the photodiodes 202 during formation and patterning of the metal layer 208. Additionally, the passivation layer may function as an etch stop layer (ESL) during formation of the openings 902, 904, and 906, as described below.

As shown in FIG. 9B, the metal layer 208 is patterned. For example, a portion of the metal layer 208 may be removed. In some implementations, a deposition tool may form a photoresist layer over and/or on the frontside surface of the metal layer 208, an exposure tool may expose the photoresist layer to a radiation source to form a pattern on the photoresist layer, and a developer tool may develop and remove portions of the photoresist layer to expose the pattern. Accordingly, an etch tool may etch (e.g., use a wet etch technique, a dry etch technique, a plasma-enhanced etch technique, and/or another type of etch technique) a portion of the metal layer 208 in order to create openings in the metal layer 208 over the photodiodes 202. In some implementations, as shown in FIG. 9B, surfaces of the photodiodes 202 may be exposed. Alternatively, surfaces of a dielectric layer or a buffer layer disposed over the photodiodes 202 may be exposed. A photoresist removal tool may remove the remaining portions of the photoresist layer (e.g., using a chemical stripper, a plasma asher, and/or another technique) after the metal layer 208 is patterned.

Even though the photodiodes 202 are approximately a same size, the openings are differently sized. For example, opening 902 may be larger than openings 904 and 906, such that a photodiode associated with opening 902 functions as an HSPD. Similarly, opening 904 may be smaller than opening 902 but larger than opening 906, such that a photodiode associated with opening 904 functions as an MSPD, and a photodiode associated with opening 906 functions as an LSPD. Because the photodiodes 202 are approximately a same size, the pixel array is regular, which increases efficacy of the isolation structures and thus decreases photodiode leakage. Additionally, formation of the isolation structure 204 is simplified, which conserves power, processing resources, and raw materials and also decreasing process windows, as compared with formation of isolation structures for an irregular pixel array. Moreover, because the openings 902, 904, and 906 are varied, the photodiodes 202 have different capture rates. Therefore, a higher dynamic range is achieved (e.g., approximately 140 dB or higher) due to an increased capacity of the pixel array. Additionally, the pixel array exhibits better dark performance as compared to a pixel array with a combination of LPDs and SPDs.

As shown in FIG. 9C, a passivation layer 908a is formed in the opening 902, a passivation layer 908b is formed in the opening 904, and a passivation layer 908c is formed in the opening 906. For example, a deposition tool may form the passivation layers 908 using a spin-coating technique, a CVD technique, a PVD technique, an ALD technique, and/or another deposition technique. The passivation layers 908 may include an oxide material, such as a silicon oxide (SiOₓ). Additionally and/or alternatively, the passivation layers 908 may include a silicon nitride (SiNₓ), a silicon carbide (SiCₓ), or a mixture thereof, such as a silicon carbon nitride (SiCN), a silicon oxynitride (SiON), or another dielectric material. In some implementations, a planarization tool planarizes the passivation layers 908 after deposition (e.g., using CMP).

As shown in FIG. 9D, color filter regions 212a, 212b, and 212c are formed for each of the photodiodes 202. In the example implementations 900, the color filter regions 212a, 212b, and 212c are formed over the passivation layers 908a, 908b, and 908c. Accordingly, a passivation layer 212d may be formed over the metal layer 208. Additionally, or alternatively, the color filter regions 212a. 212b, and 212c may be formed at least partially in the openings 902, 904, and 906. Accordingly, the passivation layer 908 may be thinner than the metal layer 208 or may be omitted altogether. In some implementations, a deposition tool may deposit the color filter regions 212 in a PVD operation, an ALD operation, a CVD operation, an epitaxy operation, an oxidation operation, and/or another deposition technique. In some implementations, a planarization tool planarizes the color filter regions 212 after deposition (e.g., using CMP).

As shown in FIG. 9E, microlenses 214 are formed for each of the photodiodes 202. In the example implementations 900, the microlenses 214 are formed over and/or on the color filter regions 212. Because the photodiodes 202 are associated with differently sized openings in the metal layer 208, the microlenses 214 may be associated with different focal lengths. For example, a microlens associated with an HSPD may be associated with a longer focal length as compared with a microlens associated with an MSPD or an LSPD. Similarly, a microlens associated with an LSPD may be associated with a shorter focal length as compared with a microlens associated with an MSPD or an HSPD. Alternatively, as described in connection with FIGS. 4A, 5A, 6A, 7A, and 8A, the photodiodes 202 may share a microlens. As a result, PDAF may be performed using separate signals from the photodiodes 202.

As further shown in FIG. 9E, an FD node 402 may be provided for each of the photodiodes 202. The FD nodes 402 may each include a drain region, such as a highly-doped n-type region (e.g., an n⁺ doped region). The photodiodes 202 thus generate photocurrent that flows from the photodiodes 202 to the corresponding FD nodes 402. Although the example implementation 900 is shown with a corresponding FD node 402 for each photodiode 202, other examples may include one or more of the photodiodes 202 sharing an FD node 402 (e.g., as shown in FIGS. 4A, FIG. 6A, or FIG. 7A, among other examples).

Additionally, a transfer (TX) gate 404 may be provided for each of the photodiodes 202 to control the transfer of photocurrent between the photodiodes 202 and the FD nodes 402. The TX gates 404 may be energized (e.g., by applying a voltage or a current to the TX gates 404) to cause conductive channels to form between the photodiodes 202 and the corresponding FD nodes 402. The conductive channels may be removed or closed by de-energizing the TX gates 404, which blocks and/or prevents the flow of photocurrent between the photodiodes 202 and the corresponding FD nodes 402. The TX gates 404 may be included in one or more dielectric layers 910.

As indicated above, FIGS. 9A-9E are provided as an example. Other examples may differ from what is described with regard to FIGS. 9A-9E. For example, the metal layer 208 may be patterned using a plurality of layers rather than a single photoresist layer. For example, the plurality of layers may include a bottom layer, a middle layer, and a photoresist layer. Additionally, or alternatively, although the example implementation 900 is described in connection with photolithography, multiple patterning techniques may be used, such as sidewall image transfer, pitch splitting, self-aligned double patterning (SADP), or directed self-assembly (DSA), among other examples.

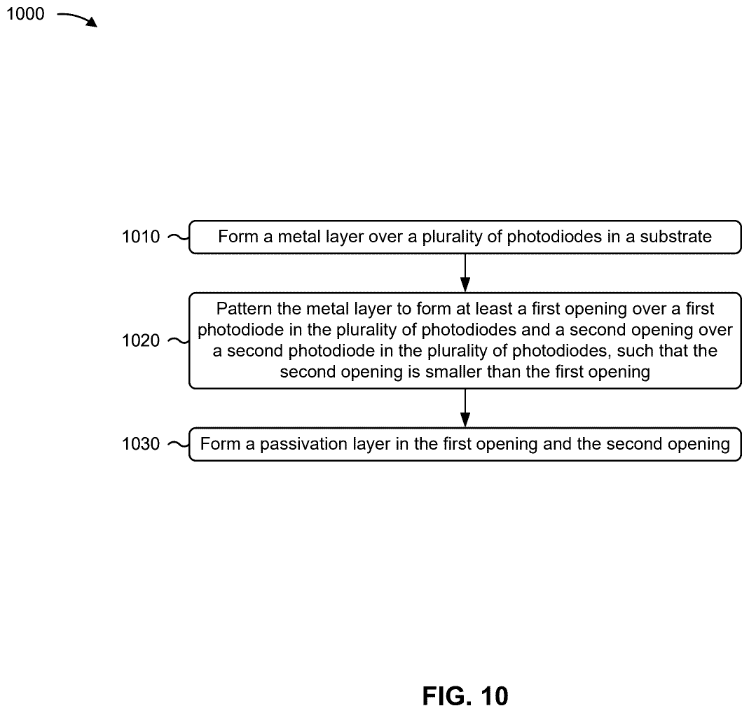

FIG. 10 is a flowchart of an example process 1000 associated with pixel sensors and methods of manufacturing the same. In some implementations, one or more process blocks of FIG. 10 are performed using one or more semiconductor processing tools referenced in connection with FIGS. 9A-9E. Additionally, or alternatively, one or more process blocks of FIG. 10 may be performed using another device or a group of devices separate from or including the one or more of the semiconductor processing tools, such as processing tools that may be included in a pixel sensor fabrication facility.

As shown in FIG. 10, process 1000 may include forming a metal layer over a plurality of photodiodes in a substrate (block 1010). For example, one or more of the semiconductor processing tools may be used to form a metal layer 208 over a plurality of photodiodes 202 in a substrate 206, as described herein.

As further shown in FIG. 10, process 1000 may include patterning the metal layer to form at least a first opening over a first photodiode in the plurality of photodiodes and a second opening over a second photodiode in the plurality of photodiodes, such that the second opening is smaller than the first opening (block 1020). For example, one or more of the semiconductor processing tools may be used to pattern the metal layer 208 to form at least a first opening 902 over a first photodiode in the plurality of photodiodes 202 and a second opening 906 over a second photodiode in the plurality of photodiodes 202, such that the second opening 906 is smaller than the first opening 902, as described herein.

As further shown in FIG. 10, process 1000 may include forming a passivation layer in the first opening and the second opening (block 1030). For example, one or more of the semiconductor processing tools may be used to form a passivation layer 908 in the first opening 902 and the second opening 906, as described herein.

Process 1000 may include additional implementations, such as any single implementation or any combination of implementations described below and/or in connection with one or more other processes described elsewhere herein.

In a first implementation, the metal layer 208 is configured to reduce crosstalk between the first photodiode and the second photodiode.

In a second implementation, alone or in combination with the first implementation, each opening has a width that is approximately a same length as a height of the opening.

In a third implementation, alone or in combination with the first implementation, each opening has a width that is longer than a height of the opening.

In a fourth implementation, alone or in combination with one or more of the first through third implementations, process 1000 includes patterning the metal layer 208 to form a third opening 904 over a third photodiode in the plurality of photodiodes 202, where the third opening 904 is larger than the second opening 906 and smaller than the first opening 902.

In a fifth implementation, alone or in combination with one or more of the first through fourth implementations, process 1000 includes forming a first microlens associated with the first photodiode and a second microlens associated with the second photodiode, where the second microlens is associated with a shorter focal length than the first microlens.

In a sixth implementation, alone or in combination with one or more of the first through fifth implementations, process 1000 includes forming a first color filter associated with the first photodiode and a second color filter associated with the second photodiode.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, patterning a metal grid of a pixel array with different sized openings over photodiodes results in a uniform pixel array of photodiodes with different sensitivities. For example, the pixel array may include LSPDs, MSPDs, and HSPDs. The LSPDs, MSPDs, and HSPDs have different capture rates. Therefore, a higher dynamic range is achieved by combining signals from LSPDs, MSPDs, and HSPDs. For example, the pixel array may achieve a dynamic range of approximately 140 dB or higher due to its increased capacity. Additionally, the pixel array exhibits better dark performance as compared to a pixel array with a combination of LPDs and SPDs. Because each photodiode in the pixel array is approximately a same size, photodiode leakage is reduced as compared with irregular pixel arrays including a combination of LPDs and SPDs.

As described in greater detail above, some implementations described herein provide a semiconductor device. The semiconductor device includes a first photodiode associated with a first opening in a metal layer. The semiconductor device includes a second photodiode associated with a second opening in the metal layer. The second opening is smaller than the first opening, and a ratio of a size of the first photodiode to a size of the second photodiode is in a range from approximately 0.9 to approximately 1.1.

As described in greater detail above, some implementations described herein provide a method. The method includes forming a metal layer over a plurality of photodiodes in a substrate. The method includes patterning the metal layer to form at least a first opening over a first photodiode in the plurality of photodiodes and a second opening over a second photodiode in the plurality of photodiodes, where the second opening is smaller than the first opening. The method includes forming a passivation layer in the first opening and the second opening.

As described in greater detail above, some implementations described herein provide a system that includes a pixel sensor. The pixel sensor includes a metal layer configured to reflect light. The pixel sensor includes a set of first photodiodes associated with a corresponding set of first openings in the metal layer. The pixel sensor includes a set of second photodiodes, each second photodiode having approximately a same size as each first photodiode, associated with a corresponding set of second openings in the metal layer, each second opening being smaller than each first opening an isolation structure. The system includes circuitry configured to output an electrical signal from the set of first photodiodes and the set of second photodiodes.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first photodiode associated with a first opening in a metal layer; and
a second photodiode associated with a second opening in the metal layer,
wherein the second opening is smaller than the first opening, and
wherein a ratio of a size of the first photodiode to a size of the second photodiode is in a range from approximately 0.9 to approximately 1.1.

2. The semiconductor device of claim 1, wherein a ratio of a width of the first opening to a pitch associated with the first photodiode is in a range from approximately 0.8 to approximately 1.0.

3. The semiconductor device of claim 1, wherein a ratio of a width of the second opening to a pitch associated with the second photodiode is in a range from approximately 0.2 to approximately 0.5.

4. The semiconductor device of claim 1, further comprising:
a third photodiode associated with a third opening in the metal layer,
wherein the third opening is larger than the second opening and smaller than the first opening.

5. The semiconductor device of claim 4, wherein a ratio of a width of the third opening to a pitch associated with the third photodiode is in a range from approximately 0.5 to approximately 0.8.

6. The semiconductor device of claim 1, further comprising:
a first microlens associated with the first photodiode; and
a second microlens associated with the second photodiode,
wherein the second microlens is associated with a shorter focal length than the first microlens.

7. The semiconductor device of claim 1, further comprising:
a first color filter associated with the first photodiode; and
a second color filter associated with the second photodiode.

8. A method, comprising:
forming a metal layer over a plurality of photodiodes in a substrate;
patterning the metal layer to form at least a first opening over a first photodiode in the plurality of photodiodes and a second opening over a second photodiode in the plurality of photodiodes, wherein the second opening is smaller than the first opening; and
forming a passivation layer in the first opening and the second opening.

9. The method of claim 8, wherein the metal layer is configured to reduce crosstalk between the first photodiode and the second photodiode.

10. The method of claim 8, wherein each opening has a width that is approximately a same length as a height of the opening.

11. The method of claim 8, wherein each opening has a width that is longer than a height of the opening.

12. The method of claim 8, further comprising:
patterning the metal layer to form a third opening over a third photodiode in the plurality of photodiodes, wherein the third opening is larger than the second opening and smaller than the first opening.

13. The method of claim 8, further comprising:
forming a first microlens associated with the first photodiode and a second microlens associated with the second photodiode, wherein the second microlens is associated with a shorter focal length than the first microlens.

14. The method of claim 8, further comprising:
forming a first color filter associated with the first photodiode and a second color filter associated with the second photodiode.

15. A system, comprising:
a pixel sensor comprising:
a metal layer configured to reflect light;
a set of first photodiodes associated with a corresponding set of first openings in the metal layer;
a set of second photodiodes, each second photodiode having approximately a same size as each first photodiode, associated with a corresponding set of second openings in the metal layer, each second opening being smaller than each first opening; and
an isolation structure; and
circuitry configured to output an electrical signal from the set of first photodiodes and the set of second photodiodes.

16. The system of claim 15, further comprising:
a floating diffusion node shared by the set of first photodiodes and the set of second photodiodes.

17. The system of claim 15, further comprising:
a first floating diffusion node for the set of first photodiodes; and
a second floating diffusion node for the set of second photodiodes.

18. The system of claim 15, further comprising:
a lateral overflow integrated capacitor associated with the set of second photodiodes.

19. The system of claim 15, wherein the pixel sensor further comprises a set of third photodiodes, each third photodiode having approximately a same size as each first photodiode, associated with a corresponding set of third openings in the metal layer, each third opening being larger than each second opening and smaller than each first opening, and wherein the system further comprises:
a floating diffusion node shared by the set of first photodiodes, the set of second photodiodes, and the set of third photodiodes.

20. The system of claim 15, wherein the pixel sensor is associated with a dynamic range of at least 140 decibels (dB).
